(19) United States
(12) Patent Application Publication
(10) Pub. No.: US 2025/0338754 A1
(43) Pub. Date: Oct. 30, 2025

(54) DISPLAY PANEL, FABRICATION METHOD OF DISPLAY PANEL, AND DISPLAY DEVICE

(71) Applicant: Xiamen Tianma Display Technology Co., Ltd., Xiamen (CN)

(72) Inventor: Shengwu ZHANG, Xiamen (CN)

(21) Appl. No.: 18/784,619

(22) Filed: Jul. 25, 2024

(30) Foreign Application Priority Data
Apr. 30, 2024 (CN) 202410545010.7

(51) Int. Cl. H10K 59/80

(52) U.S. Cl. CPC H10K 59/873

(57) ABSTRACT

A display panel includes a display region and a non-display region. The non-display region includes: a base substrate; first isolation structures surrounding an opening area; a barrier element surrounding the opening area; and a light-emitting structure including a first light-emitting portion and a second light-emitting portion. One first isolation structure includes a first surface away from the base substrate, and a first side surface and a second side surface opposite to each other. The barrier element covers the second side surface and at least a portion of the first surface. The second side surface is located on a side close to a center point of a projection of the barrier element on the base substrate. The first light-emitting portion is located on a side of the barrier element away from the base substrate. The second light-emitting portion is located on the base substrate and contacts the first side surface.

### CROSS-REFERENCE TO RELATED APPLICATION

This application claims the priority of Chinese Patent Application No. 202410545010.7, filed on Apr. 30, 2024, the content of which is incorporated herein by reference in its entirety.

### TECHNICAL FIELD

The present disclosure generally relates to the field of display technology and, more particularly, relates to a display panel and its fabrication method, and a display device.

### BACKGROUND

Some display panels use banks and metal isolation columns. The banks are used to block ink from overflowing in an inkjet printing (IJP) packaging layer, and the metal isolation columns are used to separate light-emitting film layers in the display panels to prevent water vapor from entering display regions from the light-emitting film layers.

Although the above-mentioned metal isolation columns can separate the light-emitting film layers, electrode layers in the separated light-emitting film layers may overlap with the sides of the metal isolation columns. Since the electrode layers are in a conductive state, dark spots and holes will appear on the display panel. Further, the banks and isolation columns will also take up a large space, which is not beneficial to achieving narrow frames of the display panels.

### SUMMARY

One aspect of the present disclosure provides a display panel. The display panel includes a display region and a non-display region. The non-display region includes: a base substrate including an opening area; first isolation structures on the base substrate and surrounding a periphery of the opening area; a barrier element on the substrate and surrounding the periphery of the opening area; and a light-emitting structure including a first light-emitting portion and a second light-emitting portion. One first isolation structure includes a first surface on a side away from the base substrate, and a first side surface and a second side surface opposite to each other in a direction parallel to the base substrate. The barrier element covers the second side surface and at least a portion of the first surface, and the second side surface is located on a side close to a center point of a vertical projection of the barrier element on the base substrate. The first light-emitting portion is located on a side of the barrier element away from the base substrate, the second light-emitting portion is located on the base substrate and in contact with the first side surface, and the first light-emitting portion and the second light-emitting portion are spaced apart.

Another aspect of the present disclosure provides a fabrication method of a display panel. The method includes forming a display region and a non-display region. Forming the non-display region includes: providing a base substrate including an opening area; forming first isolation structures on the base substrate and surrounding a periphery of the opening area; forming a barrier element on the substrate and surrounding the periphery of the opening area; and forming a light-emitting structure including a first light-emitting portion on the barrier element and a second light-emitting portion on the base substrate. One first isolation structure includes a first surface on a side away from the base substrate, and a first side surface and a second side surface opposite to each other in a direction parallel to the base substrate. The barrier element covers the second side surface and at least a portion of the first surface, and the second side surface is located on a side close to a center point of a vertical projection of the barrier element on the base substrate. The first light-emitting portion is located on a side of the barrier element away from the base substrate, the second light-emitting portion is located on the base substrate and in contact with the first side surface, and the first light-emitting portion and the second light-emitting portion are spaced apart.

Another aspect of the present disclosure provides a display device. The display device includes a display panel. The display panel includes a display region and a non-display region. The non-display region includes: a base substrate including an opening area; first isolation structures on the base substrate and surrounding a periphery of the opening area; a barrier element on the substrate and surrounding the periphery of the opening area; and a light-emitting structure including a first light-emitting portion and a second light-emitting portion. One first isolation structure includes a first surface on a side away from the base substrate, and a first side surface and a second side surface opposite to each other in a direction parallel to the base substrate. The barrier element covers the second side surface and at least a portion of the first surface, and the second side surface is located on a side close to a center point of a vertical projection of the barrier element on the base substrate. The first light-emitting portion is located on a side of the barrier element away from the base substrate, the second light-emitting portion is located on the base substrate and in contact with the first side surface, and the first light-emitting portion and the second light-emitting portion are spaced apart.

Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a partially cross-sectional view of an exemplary display panel consistent with various disclosed embodiments in the present disclosure.

FIG. 2 illustrates a partially top view of an exemplary display panel consistent with various disclosed embodiments in the present disclosure.

FIG. 3 illustrates a partially cross-sectional view of another exemplary display panel consistent with various disclosed embodiments in the present disclosure.

FIG. 4 illustrates a flow chart of an exemplary fabrication method of a display panel consistent with various disclosed embodiments in the present disclosure.

FIG. 5 illustrates a partially cross-sectional view after forming a first isolation structure on a substrate in an exemplary fabrication method of a display panel consistent with various disclosed embodiments in the present disclosure.

FIG. 6 illustrates a partially cross-sectional view after forming a barrier element including an organic insulating layer and an inorganic insulating layer on the substrate in FIG. 5, consistent with various disclosed embodiments in the present disclosure.

FIG. 7 illustrates a partially cross-sectional view after forming a barrier element including an inorganic insulating layer on the substrate in FIG. 5, consistent with various disclosed embodiments in the present disclosure.

FIG. 8 illustrates a partially cross-sectional view after forming a light-emitting structure and a second isolation structure on the substrate in FIG. 7, consistent with various disclosed embodiments in the present disclosure.

FIG. 9 illustrates an exemplary display device consistent with various disclosed embodiments in the present disclosure.

### DETAILED DESCRIPTION

Reference will now be made in detail to exemplary embodiments of the disclosure, which are illustrated in the accompanying drawings. Hereinafter, embodiments consistent with the disclosure will be described with reference to drawings. In the drawings, the shape and size may be exaggerated, distorted, or simplified for clarity. Wherever possible, the same reference numbers will be used throughout the drawings to refer to the same or like parts, and a detailed description thereof may be omitted.

Further, in the present disclosure, the disclosed embodiments and the features of the disclosed embodiments may be combined under conditions without conflicts. It is apparent that the described embodiments are some but not all of the embodiments of the present disclosure. Based on the disclosed embodiments, persons of ordinary skill in the art may derive other embodiments consistent with the present disclosure, all of which are within the scope of the present disclosure.

Moreover, the present disclosure is described with reference to schematic diagrams. For the convenience of descriptions of the embodiments, the cross-sectional views illustrating the device structures may not follow the common proportion and may be partially exaggerated. Besides, those schematic diagrams are merely examples, and not intended to limit the scope of the disclosure. Furthermore, a three-dimensional (3D) size including length, width, and depth should be considered during practical fabrication.

In the present disclosure, relational terms such as first and second are only used to distinguish one entity or operation from another entity or operation, and do not necessarily require or imply any such actual relationship between these entities or operations or order. Moreover, the terms “including”, “comprising” or any other variants thereof are intended to cover non-exclusive inclusion, such that a process, method, article, or device that includes a series of elements includes not only those elements, but also those that are not explicitly listed or also include elements inherent to this process, method, article or equipment. If there are no more restrictions, the elements defined by the sentence “including . . . ” do not exclude the existence of other same elements in the process, method, article, or equipment that includes the elements.

It should be understood that when describing the structure of a component, when a layer or region is referred to as being “on” or “above” another layer or another region, the layer or region may be directly on the other layer or region, or indirectly on the other layer or region, for example, layers/components between the layer or region and another layer or another region. And, for example, when the component is reversed, the layer or region may be “below” or “under” the other layer or region. In the present disclosure, the term “electrical connection” refers to that two components are directly electrically connected with each other, or the two components are electrically connected via one or more other components.

In a display panel, metal isolation columns of the display panel isolate an OLED film layer to prevent water vapor from entering a display region from the OLED film layer. Although the metal isolation column design can isolate the OLED film layer, an electrode layer of the isolated OLED film layer will still overlap with the side of the metal isolation columns. The electrode layer is in a state of full-surface conduction, and dark spots and holes will appear on the display panel. The present disclosure provides a display panel, a fabrication method thereof, and a display device, to at least partially alleviate the above problems.

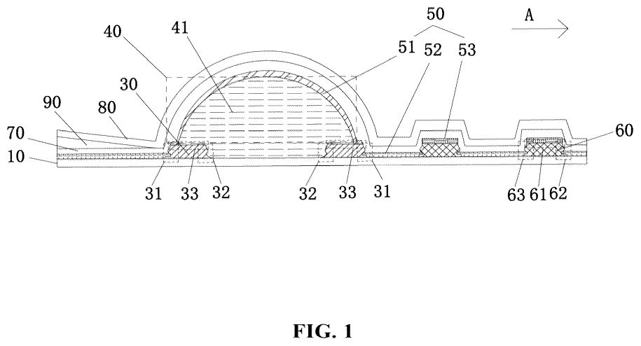

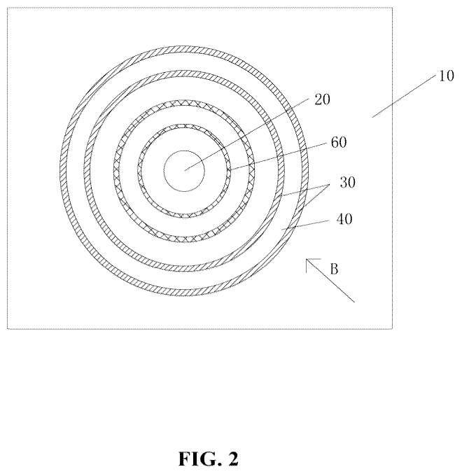

The present disclosure provides a display panel. As shown in FIG. 1 and FIG. 2, in one embodiment, the display panel may include a display region and a non-display region. The non-display region may include a base substrate 10, first isolation structures 30, a barrier element 40 and a light-emitting structure 50. The base substrate 10 may have an opening area 20; and the first isolation structures 30 may be disposed on the base substrate 10 and surround an outer periphery of the opening area 20. One first isolation structure 30 may include a first surface at a side away from the base substrate 10, and a first side surface and a second side surface opposite to each other in a direction A parallel to the base substrate 10. The barrier element 40 may be located on the base substrate 10 and surround the outer periphery of the opening area 20. The barrier element 40 may cover the second side surface and at least a portion of the first surface. The second side surface may be located on a side close to a center point of a vertical projection of the barrier element 40 on the base substrate 10. The light-emitting structure 50 may include a first light-emitting portion 51 and a second light-emitting portion 52. The first light-emitting portion 51 may be located on a side of the barrier element 40 away from the base substrate 10, and the second light-emitting portion 52 may be located on the base substrate 10 and contact the first side surface. The first light-emitting portion 51 and the second light-emitting portion 52 may be arranged at intervals.

To avoid ink overflow and dark spot problems, a display panel in the existing technologies adopts two structures including an isolation column and a barrier element. The isolation column has a certain height difference with the substrate, such that the light-emitting layer is stretched when the light-emitting layer is deposited, and the light-emitting layer is broken at where it is stretched, thereby isolating the light-emitting layer. Although the light-emitting layer is isolated on the side wall of the isolation column, the electrode layer at the cut surface produces creepage along the side wall of the isolation column, such that the electrode layer between the isolated light-emitting layer is still conductive and a small amount of water vapor from the outside will follow into the display region. Therefore, there is still a risk of dark spots and holes in the display panel. In the present disclosure, the side walls of the first isolation structures in the display panel may divide the light-emitting structure into two portions. The side walls may cause a larger creepage distance or obstruction between the isolated portions of the light-emitting structure, preventing creepage from occurring between the electrode layer in the isolated portions of the light-emitting structure. Also, the disconnected light-emitting structure may be located in the non-display region. Therefore, the display of the display panel may not be affected, and also a small amount of water vapor may be prevented from entering the display region along the creepage of the electrode layer. The first isolation structures may also have a waterproof property, which prevents water vapor from entering the display region from the outside through the first isolation structures and entering the display region of the display panel through the light-emitting structure, thereby avoiding the generation of black spots in the display region. The barrier element may cover the second side surface of the first isolation structures and at least a portion of the first surface of the first isolation structures, thereby blocking the connection between the electrode layer of the first light-emitting portion and the second light-emitting portion. The electrode layer may be electrically isolated, avoiding the appearance of dark spots and holes in the display panel, and preventing ink from overflowing from the display region.

As shown in FIG. 1 and FIG. 2, the display panel may include the base substrate 10, the first isolation structures 30, the barrier element 40 and the light-emitting structure 50. The barrier element 40 and the first isolation structures 30 may be arranged around the opening area 20 of the base substrate 10, and the first side surface of the first isolation structures 30 may divide the light-emitting structure 50 into the first light-emitting portion 51 and the second light-emitting portion 52. The barrier element 40 may cover the second side surface 32 and a portion of the first surface 33 of the first isolation structures 30, and insulate the first isolation structures 30, the first light-emitting portion 51 and the second light-emitting portion 52, to disconnect the electrode layer in the first light-emitting portion 51 and the electrode layer in the second light-emitting portion 52, thereby avoiding the occurrence of black spots on the display panel because of conduction of the electrode layers.

In some embodiments, as shown in FIG. 1 and FIG. 2, the first isolation structures 30 may include the first side surface 31 and the second side surface 32 opposite to each other in the direction A parallel to the base substrate 10, and the first side surface 31 may be an uneven surface.

As shown in FIG. 1 and FIG. 2, the morphology of the first side surface 31 of the first isolation structures 30 may be set to be an uneven surface with both grooves and protrusions. Since the light-emitting structure 50 has a relatively small thickness in the actual process, when the light-emitting structure 50 is deposited and prepared, the light-emitting structure 50 may be easily disconnected at the first side surface 31 of the first isolation structures 30 with the above-mentioned morphology to form the above-mentioned first light-emitting portion 51 and the second light-emitting portion 52. The first side surface 31 with the uneven surface may also isolate the first light-emitting portion 51 and the second light-emitting portion 52, thereby not only avoiding the creepage phenomenon between the electrode layers but also preventing water vapor from entering the display region. The phenomenon of dark spots and black spots may be prevented. The barrier element 40 with a raised morphology may cover the second side surface 32 and a portion of the first surface 33, such that the first isolation structures 30 may block the ink layer on the basis of blocking the light-emitting structure 50. Further, by setting the barrier element 40 and the first isolation structures 30, the ink and water vapor may be blocked, but also only a structure including the barrier element 40 and the first isolation structures 30 is needed to be designed without the need to set up other isolation structures. The area of the outer boundary of the opening area may be reduced, saving the area of the non-display region, reducing the wiring space, and further facilitating the realization of a narrow frame of the display panel.

In one embodiment shown in FIG. 1 and FIG. 2, the first isolation structures 30 may be made of a material including stainless steel, aluminum alloy, galvanized steel plate, titanium alloy, copper alloy, or a combination thereof. Those skilled in the art may make a reasonable selection based on the type of material of the first isolation structures, and the present disclosure does not specifically limit this.

In some embodiments shown in FIG. 1 and FIG. 2, the first isolation structures 30 may include the first side surface 31 and the second side surface 32 opposite to each other in the direction A parallel to the base substrate 10, and the first side surface 31 may include at least one groove. A portion of the second light-emitting portion 52 may contact the first side surface 31.

In the actual process of preparing and forming the light-emitting structure 50, to disconnect the light-emitting structure 50 at the first isolation structures 30, the side of the light-emitting structure 50 in contact with the first isolation structure 30 may be non-smoothed. In one embodiment, the first side surface 31 may be grooved such that the first side surface 31 includes at least one groove and the light-emitting structure 50 may be broken at the at least one groove. When the first side surface 31 with the above-mentioned groove morphology is not provided, even if the light-emitting structure is separated into the first light-emitting portion 51 and the second light-emitting portion 52, the electrode layer of the first light-emitting portion 51 and the electrode layer of the second light-emitting portion 52 may still have a creepage phenomenon, and the electrode layers may be still in a conductive state. In the present embodiment, by using the first side surface 31 with a groove morphology, the light-emitting structure 50 may be disconnected to form the first light-emitting portion 51 and the second light-emitting portion 52. The first side surface 31 with a groove morphology may make the electrode layer of the first light-emitting portion 51 and the electrode layer of the second light-emitting portion 52 have an uneven creepage path and a large creepage distance, therefore creepage between the electrode layers may be difficult to form and the electrode layers may be disconnected. The material properties of the first isolation structures 30 in the above-mentioned embodiments of the present disclosure may determine its ability to isolate water vapor, and may isolate water vapor from the outside that reaches the disconnection point of the light-emitting structure 50, thereby ensuring that water vapor does not enter the display region from the first isolation structures 30, and can also prevent external water vapor from entering the display region through the connection between the first light-emitting portion 51 and the second light-emitting portion 52.

In another embodiment, as shown in FIG. 1 and FIG. 2, the first isolation structures 30 may include the first surface 33 on the side away from the base substrate 10. The first isolation structures 30 may include the first side surface 31 and the second side surface 32 opposite to each other in the direction A parallel to the base substrate 10. The barrier element 40 may include an organic insulating layer 41. The organic insulating layer 41 may cover the second side surface 32 and at least a portion of the first surface 33.

In the present embodiment, as shown in FIG. 1 and FIG. 2, the display panel may also include an ink layer 90. The ink layer 90 may be a fluid encapsulation layer in the display panel. The barrier element 40 may isolate a portion of the ink layer 90 in the display panel outside the opening area 20. The cross-section of the second light-emitting portion 52 may directly contact the first isolation structures 30. The organic insulating layer 41 may prevent the ink layer 90 from overflowing, and also insulate the first isolation structures 30 to prevent the second light-emitting portion 52 from being electrically connected to other first isolation structures. It should noted that the barrier element 40 shown in FIG. 1 only includes the organic insulating layer 41, but in other embodiments, the barrier element 40 may also include other film layers, which is not specifically limited in the embodiments of the present disclosure.

In one embodiment, as shown in FIG. 1 and FIG. 2, the coverage rate of the organic insulating layer 41 on the first surface of the first isolation structures 30 may reach more than 90%, to reduce the contact area between the first light-emitting portion 51 and the first isolation structures 30, thereby reducing the risk of the first light-emitting portion 51 being connected to the second light-emitting portion 52 through the first isolation structures 30. Therefore, the barrier element 40 with the organic insulating layer 41 may have a better insulation effect. The organic insulating layer 41 may be made of a material including rubber, polymer, polytetrafluoroethylene, polyester film, polyethylene film or a combination thereof, and the present disclosure does not have any limit on this.

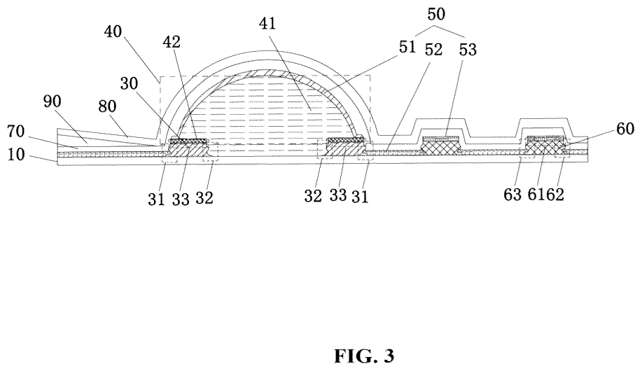

In another embodiment, as shown in FIG. 3, the first isolation structures 30 may include the first surface 33 on the side away from the base substrate 10. The first isolation structures 30 may include the first side surface 31 and the second side surface 32 opposite to each other in the direction A parallel to the base substrate 10. The barrier element 40 may include an organic insulating layer 41 and an inorganic insulating layer 42. The organic insulating layer 41 may cover the second side surface 32 and at least a portion of the first surface 33. The inorganic insulating layer 42 may cover at least a portion of the first surface, and the organic insulating layer 41 may cover at least a portion of the inorganic insulating layer 42.

In the present embodiment, as shown in FIG. 3, the barrier element 40 may include the organic insulating layer 41 and the inorganic insulating layer 42. There are process limitations in directly forming the organic insulating layer 41 on the first isolation structures 30, which may cause the organic insulating layer 41 to be difficult to achieve 100% coverage on the first surface. Since the inorganic insulating layer 42 is not easily limited by the process, the inorganic insulating layer 42 may be able to completely cover the above first surface, such that the first light-emitting portion 51 and the first isolation structures 30 may be insulated from each other to completely block the connection between the first light-emitting portion 51 and the second light-emitting portion 52. Also, the organic insulating layer 41 may cover the inorganic insulating layer 42, and the organic insulating layer 41 may be located between the first isolation structures 30 and cover a portion of the first surface of the first isolation structures 30. The organic insulating layer 41 overall may be similar to the shape of a hemisphere, which is mainly used to block the overflow of the ink layer 90. Further, since the connection between the first light-emitting portion 51 and the second light-emitting portion 52 is blocked, water vapor may be also prevented from entering the display region through the first light-emitting portion 51 and the second light-emitting portion 52. The other structures in FIG. 3 are the same as those described in FIG. 1, and are not repeated herein.

In the above optional embodiment, as shown in FIG. 3, the inorganic insulating layer 42 may be made of a material including aluminum oxide, silica gel, silicon carbide, boron nitride, or any combination thereof. Those skilled in the art may make a reasonable selection based on the type of material for the inorganic insulating layer, and the present disclosure does not specifically limit this.

In some embodiments, the first isolation structure may include the first surface on the side away from the base substrate, and the area of the first surface covered by the barrier element may be larger than 90% of the total area of the first surface.

In the above optional embodiments, when the organic insulating layer is directly deposited on the first surface or when the inorganic insulating layer is deposited first, the coverage rate of the barrier element on the first surface may be larger than 90%. In the actual process, when the barrier element is an organic insulating layer, it may be difficult for the organic insulating layer to completely cover the first surface, and a portion of the first light-emitting portion may be in contact with the first spacing layer. The insulating layer of the first light-emitting portion may be in contact with the first spacing layer, to play a certain insulating role. The organic insulating layer may usually cover up to about 90% of the first surface, such that the contact area between the first light-emitting portion and the first spacing layer is as small as possible to enhance the insulation effect between the first light-emitting portion and the first spacing layer. When the barrier element includes both the organic insulating layer and the inorganic insulating layer, the inorganic insulating layer may completely cover the first surface, thereby achieving a coverage rate of 100% to completely isolate the first light-emitting portion from the first isolation structure. At this time, the organic insulating layer may be arranged on the inorganic insulating layer to form a protruding structure, which may not only ensure complete insulation between the first light-emitting portion and the second light-emitting portion, but also prevent overflow of the ink layer.

In some other embodiments, as shown in FIG. 1 to FIG. 3, the display panel may include two first isolation structures 30. In a direction B from the barrier element 40 to the opening area 20, the barrier element 40 may include a first end and a second end opposite to each other, and each of the first end and the second end may be in contact with a first surface 33 of a corresponding one of the two first isolation structures 30.

In the above embodiments, as shown in FIG. 1 to FIG. 3, the barrier element 40 may be located between the two first isolation structures 30, and cover a portion of the first surfaces 33 of the two first isolation structures 30. The organic insulating layer 41 (or the inorganic insulating layer 42) at the first end and the second end of the barrier element 40 may be respectively in contact with the first surfaces 33 of the two first isolation structures 30. One of the two first isolation structures 30 may also have only one side, and those skilled in the art may reasonably set the number and setting position of the first isolation structures according to the use scenario of the device, and the present disclosure does not have limit on this.

By setting the combined structure of the barrier element and the first isolation structures, the ink overflow of the ink layer may be blocked, and the water vapor transmission of the light-emitting structure may also be blocked. When the use environment of the device does not require a strong water vapor isolation requirement, other water vapor isolation structures may be less or even may not be made, which reduces the layout area of other water vapor isolation structures and is conducive to the realization of a narrower frame.

In some optional embodiments, as shown in FIG. 1 to FIG. 3, the non-display region may further include at least one second isolation structure 60 on the base substrate 10, and the at least one second isolation structures 60 may be spaced apart along a direction B from the barrier element 40 to the opening area 20.

When there is only one barrier element 40 and one first isolation structure 30 to block water vapor, when the device needs to be strictly isolated from water vapor, a small amount of water vapor will still enter the display region, causing the liquid level of the ink layer 90 to rise after absorbing water vapor and resulting in overflow. The entry of water vapor will also cause problems such as black spots and holes in the display region. In the above optional embodiments, as shown in FIG. 1 to FIG. 3, the at least one second isolation structure 60 may be further provided on the side of the barrier element 40 close to the opening area 20. The material of the at least one second isolation structure 60 may be the same as that of the first isolation structures 30. To further improve the isolation of water vapor, the at least one second isolation structure 60 may be provided in the direction from the barrier element 40 to the opening area 20. When the light-emitting structure 50 is deposited, the light-emitting structure 50 will may be disconnected at the two sides of the at least one second isolation structure 60, thereby adding a barrier element to isolate water vapor for the display panel, greatly reducing the risk of water vapor entering the display region, and indirectly reducing the risk of overflow of the ink layer 90.

In some optional embodiments, as shown in FIG. 1 and FIG. 3, in the direction B from the barrier element 40 to the opening area 20, the at least one second isolation structure 60 may include a third side surface and a fourth side surface opposite to each other, and the third side surface and/or the fourth side surface may be uneven surfaces.

In the above optional embodiments, as shown in FIG. 1 and FIG. 3, the morphology of the at least one second isolation structure 60 may be different from that of the first isolation structures 30. The first isolation structures 30 may include at least one groove on at least one side surface not covered by the organic insulating layer 41, and two sides of the at least one second isolation structure 60 may both include at least one groove.

In some optional embodiments, as shown in FIG. 1 and FIG. 3, the at least one second isolation structure 60 may include a second surface 61 on the side away from the base substrate 10, and the light-emitting structure 50 may further include a third light-emitting portion 53 located on the second surface 61. The third light-emitting portion 53 may be in contact with the second surface 61.

In the above optional embodiments, as shown in FIG. 1 and FIG. 3, the light-emitting structure 50 may be separated into the second light-emitting portion 52 and the third light-emitting portion 53 by the at least one second isolation structure 60. The third light-emitting portion 53 may be located on the second surface 61 of the at least one second isolation structure 60, and water vapor may be isolated at the second light-emitting portion 52, such that water vapor may be prevented from entering the third light-emitting portion 53.

In some other embodiments, as shown in FIG. 1 and FIG. 3, the third light-emitting portion 53 may not be in contact with the second light-emitting portion 52.

In the above optional embodiment, as shown in FIG. 1 and FIG. 3, both sides of the second isolation structure 60 may have at least one groove, and the grooves may separate the light-emitting structure 50 into the second light-emitting portion 52 and the third light-emitting portion 53. The cutoff portion of the second light-emitting portion 52 may be located on the grooves on the sides of the at least one second isolation structure 60, and may not contact the above-mentioned third light-emitting portion 53. Since the side walls of the at least one second isolation structure 60 have the morphology of grooves and protrusions, there may be an uneven creepage path and a sufficiently large creepage distance between the second light-emitting portion 52 and the third light-emitting portion 53. Therefore, it may be difficult to generate creepage between the second light-emitting portion 52 and the third light-emitting portion 53, and the electrode layers in the second light-emitting portion 52 and the third light-emitting portion 53 may be disconnected, thereby blocking the transmission of water vapor.

In some optional embodiments, the first isolation structure may include one first surface on the side away from the base substrate, and the first isolation structure may include the first side surface and the second side surface opposite to each other in the direction parallel to the base substrate. Each of the first light-emitting portion and the second light-emitting portion may include a light-emitting layer, an electrode layer and an insulating layer. The electrode layer may be located on both sides of the light-emitting layer perpendicular to the base substrate. A portion of the insulating layer in the first light-emitting portion may be in contact with the first surface, and another portion of the insulating layer in the first light-emitting portion may be in contact with a surface of the inorganic insulating layer away from the base substrate. And/or, the insulating layer in the second light-emitting portion may be located between the electrode layer and the first side surface.

In the above optional embodiments, the first light-emitting portion, the second light-emitting portion and the third light-emitting portion in the light-emitting structure may all have multiple functional layers, and the multiple functional layers in each of the first light-emitting portion, the second light-emitting portion and the third light-emitting portion in the light-emitting structure may include one light-emitting layer, one electrode layer and one insulating layer. The insulating layer of the first light-emitting portion may be arranged on the outermost side of the functional layer, that is, the insulating layer may contact the side surface of the inorganic insulating layer away from the first surface, or directly contact the first surface (second surface). The insulating layer of the second light-emitting portion may contact the side of the first isolation structures (the at least one second isolation structure), and the insulating layer of the third light-emitting portion may be in contact with the second surface to ensure that there is no electrical connection between the electrode layers of the first light-emitting portion, the second light-emitting portion and the third light-emitting portion. The risk of black spots in the display region may be further reduced. Also, the electrode layers between the first light-emitting portion, the second light-emitting portion and the third light-emitting portion may be electrically disconnected, which may also improve the detection stability of the display panel under high temperature and high humidity conditions, thereby improving the electrostatic discharge capability of the holes set in the display panel.

In some optional embodiments, as shown in FIG. 1 and FIG. 3, a portion of the second light-emitting portion 52 may contact the at least one second isolation structure 60 on a side of the at least one second isolation structure 60 close to the opening area 20, and a portion of the second light-emitting portion 52 may contact the at least one second isolation structure 60 on another side of the at least one second isolation structure 60 away from the opening area 20.

In the above optional embodiments, as shown in FIG. 1 and FIG. 3, because of the provision of the first isolation structures 30 and the at least one second isolation structure 60, there may be two manners where the second light-emitting portion 52 is formed. One manner may be that one side of the second light-emitting portion 52 contacts the first isolation structures 30 and the other side contacts the at least one second isolation structure 60. Another manner may be that one side of the second light-emitting portion 52 contacts the surface of one side of the at least one second isolation structure 60 close to the opening area 20 and the other side of the second light-emitting portion 52 contacts the surface of one side of another second isolation structure 60 away from the opening area 20.

In some optional embodiments, as shown in FIG. 1 and FIG. 3, the at least one second isolation structure 60 may include a third side surface 62 and a fourth side surface 63 opposite to each other, and at least one of the third side surface 62 and the fourth side surface 63 may be an uneven surface. The uneven surface may include at least one groove, and a portion of the second light-emitting portion 52 may be in contact with the uneven surface.

In the above optional embodiments, as shown in FIG. 1 and FIG. 3, when the light-emitting structure 50 is separated to form the second light-emitting portion 52, the two sides of the broken second light-emitting portion 52 may contact the side of the first isolation structure 30 or the second isolation structure 60 with the groove, such that the light-emitting structure 50 is separated at the uneven part by making the uneven side surfaces of the first isolation structure 30 and the second isolation structure 60. Therefore, a part of the light-emitting structure 50 may form the second light-emitting portion 52. Because of the isolation structures with uneven morphologies, no creepage connection may be generated between the second light-emitting portion 52 and the third light-emitting portion 53, further isolating the water vapor.

In the above optional embodiments, at least one groove may be etched on the sides of the first isolation structure and the second isolation structure, and the morphology of the at least one groove may cause the light-emitting structure to be isolated. When the amplitude of the protrusion is too slow, the light-emitting structure may not be isolated, and it may be impossible to prevent water vapor from passing through the electrode layers of the light-emitting structure into the display region of the display panel. Therefore, when protrusions are formed on the sides of the first isolation structure and the second isolation structure, the steepness of the protrusions may be increased, thereby effectively preventing the protrusion from being very slow to cause the light-emitting structure to be directly deposited on the protrusion surfaces. Preferably, the disconnected light-emitting structure may fall into the grooves on the sides of the isolation structures, such that there is a larger and steeper creepage path between the disconnected light-emitting structure. Therefore, basically no creepage phenomenon may occur between the disconnected light-emitting structure, realizing electrical disconnection of the electrode layer and improving the detection stability of the display panel under high temperature and high humidity conditions. The electrostatic discharge capability of the holes set in the display panel may be also improved.

In some optional embodiments, as shown in FIG. 1 and FIG. 3, the first isolation structure 30 may include a first side surface 31 and a second side surface 32 opposite to each other in the direction A parallel to the base substrate 10. The first side surface 31 may include a first portion not covered by the light-emitting structure 50, and the non-display region may further include a first encapsulation layer 70. The first encapsulation layer 70 may cover a side of the light-emitting structure 50 away from the base substrate 10 and the first portion.

In the above optional embodiments, as shown in FIG. 1 and FIG. 3, the first isolation structure 30 and the second isolation structure 60 may separate the light-emitting structure 50, and there may be some areas on the sides of the first isolation structure 30 and the second isolation structure 60 that are not covered by the light-emitting structure 50. The first encapsulation layer 70 may cover the above area and the surface of the side of the light-emitting structure 50 away from the base substrate 10. The first encapsulation layer 70 may be located on the side of the ink layer 90 close to the base substrate 10.

In some optional embodiments, as shown in FIG. 1 and FIG. 3, the non-display region may further include a second encapsulation layer 80, and the second encapsulation layer 80 may be located on the side of the first encapsulation layer 70 away from the base substrate 10.

In the above optional embodiment, as shown in FIG. 1 and FIG. 3, the second encapsulation layer 80 may be used to encapsulate the entire structure of the display panel as a whole, and the second encapsulation layer 80 may cover the ink layer 90 and the first encapsulation layer 70.

In the above optional embodiment, the materials of the first encapsulation layer and the second encapsulation layer may be independently selected from any one or more of polyimide resin, polytetrafluoroethylene, glass fiber reinforced polyimide, polystyrene, polyimide film, or polyester film, and the present disclosure has no limit on this.

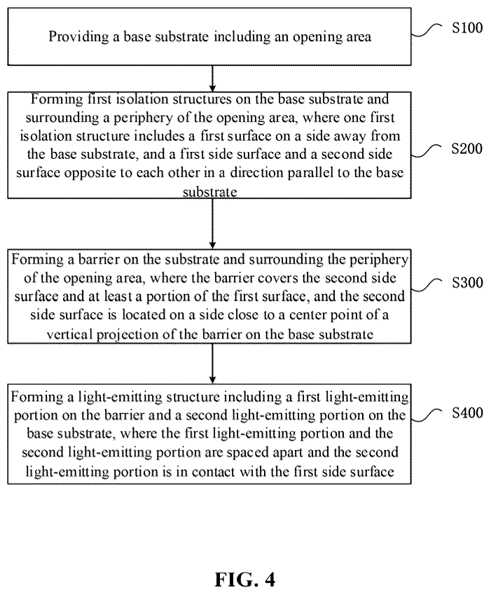

The present disclosure also provides a fabrication method of a display panel. As shown in FIG. 4, in one embodiment, the method may include forming a display region and forming a non-display region.

Forming the non-display region may include:
S100: providing a base substrate, where the base substrate includes an opening area;
S200: forming a first isolation structure on the base substrate, where: the first isolation structure is located on the base substrate and surrounds the periphery of the opening area, the first isolation structure has a first surface on a side away from the base substrate, and the first isolation structure has a first side surface and a second side surface opposite to each other in a direction parallel to the base substrate;
S300: forming a barrier element on the base substrate, where: the barrier element surrounds the periphery of the opening area, the barrier element covers at least a portion of the first surface, the second side surface is located on a side close to the center point of the vertical projection of the barrier element on the substrate, and the barrier element covers the second side surface; and
S400: forming a first light-emitting portion on the barrier element, and forming a second light-emitting portion on the base substrate, where: the first light-emitting portion and the second light-emitting portion are spaced apart, and the second light-emitting portion is in contact with the first side surface.

The display panel prepared by the above-mentioned fabrication method may avoid the situation where black spots and holes are generated in the display region. The barrier element and the first isolation structure may be formed on the above-mentioned base substrate, which may prevent the ink of the ink layer from overflowing and prevent the external water vapor from entering the display region. The first isolation structure may separate the light-emitting structure into the first light-emitting portion and the second light-emitting portion, and the first light-emitting portion and the second light-emitting portion may not be in contact. The above-mentioned side wall may cause a large creepage distance or obstruction between the isolated light-emitting portions, which may basically not cause creepage between the electrode layers in the isolated light-emitting portions. The disconnected light-emitting portions may not affect the display of the display panel in the non-display region, and may also prevent a small amount of water vapor from entering the display region through the creepage of the electrode layers. The barrier element may also block the ink layer of the display region from overflowing. The display panel obtained by the above-mentioned fabrication method may not only block the ink layer from overflowing, but also block the entry of water vapor. In general, no additional isolation structure may be required, thereby reducing the boundary of the opening area, and reducing the proportion of the non-display region in the display panel, to achieve a narrow frame design. The exemplary embodiments of the fabrication method of the display panel provided by the present disclosure will be described in more detail below in conjunction with the accompanying drawings. However, these exemplary embodiments may be implemented in a variety of different forms and should not be interpreted as being limited to the embodiments described herein. It should be understood that these embodiments are provided to make the disclosure of the present disclosure thorough and complete, and to fully convey the concepts of these exemplary embodiments to those of ordinary skill in the art.

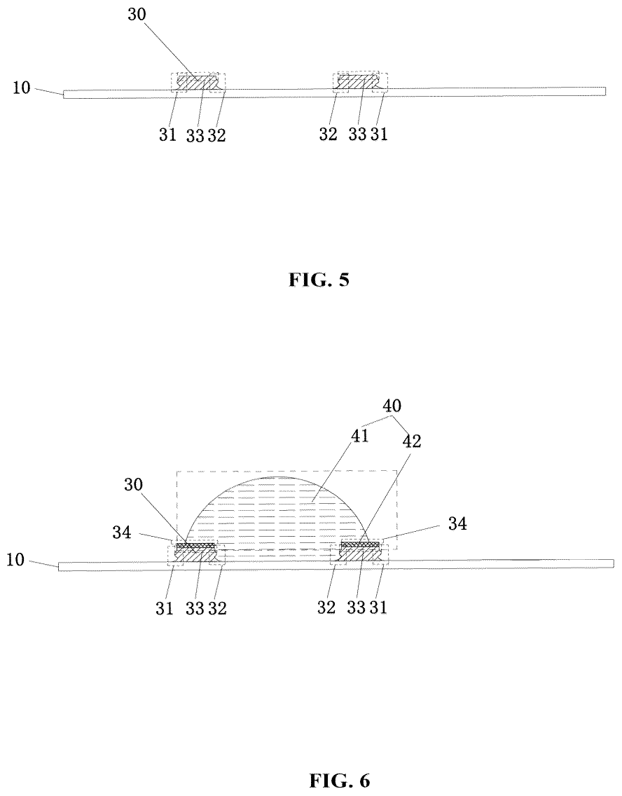

As shown in FIG. 5, in S100, the base substrate 10 may be provided, and the base substrate 10 may include the opening area.

In one embodiment, the base substrate 10 may be a thin film transistor array base substrate, and the base substrate 10 may include at least one opening area.

As shown in FIG. 5, after providing the base substrate 10, in S200, the first isolation structure 30 may be formed on the base substrate 10. The first isolation structure 30 may be disposed on the base substrate 10 and surround the periphery of the opening area. The first isolation structure 30 may include the first surface 33 on the side away from the base substrate 10. The first isolation structure 30 may include the first side surface 31 and the second side surface 32 opposite to each other in the direction parallel to the base substrate 10.

In some embodiments, as shown in FIG. 5, at least one first isolation structure 30 may be formed around the opening area. One first isolation structure 30 may include the first surface 33 on the side away from the base substrate 10. The first isolation structure 30 may include the first side surface 31 and the second side surface 32 opposite to each other in the direction to the opening area. The first isolation structure 30 may be made of a metal material that is able to isolate water vapor.

In some optional embodiments, as shown in FIG. 5, forming the first isolation structure 30 on the base substrate 10 may include: depositing the first isolation structure 30 on the base substrate 10; etching at least one groove on the first side surface 31 of the first isolation structure 30.

In the above optional embodiments, as shown in FIG. 5, at least one side surface of the first isolation structure 30 may be etched such that at least one side surface has at least one groove. The at least one side surface may be one side surface of the first isolation structure 30 close to the opening area, and another side surface of the first isolation structure 30 away from the opening area may be covered by the barrier element and may not be etched.

After forming the first isolation structure, as shown in FIG. 6, in S300, the barrier element 40 may be formed on the base substrate 10. The barrier element 40 may surround the periphery of the opening area, and may cover at least a portion of the first surface 33. The second side surface 32 may be located close to the center point of the vertical projection of the barrier element 40 on the base substrate 10 and the barrier element 40 may cover the second side surface 32.

In one embodiment, as shown in FIG. 6, the barrier element 40 may be formed at the periphery of the opening area, and an ink layer may be provided in the display panel. The ink layer may be a fluid encapsulation layer in the display panel. The barrier element 40 may be used to prevent the ink of the ink layer from overflowing. The barrier element 40 may cover at least a portion of the first surfaces 33 of the two first isolation structures 30 in the figure and completely cover the second side surfaces 32 of the two first isolation structures 30. The barrier element 40 may also form a protrusion to prevent the overflow of the ink layer.

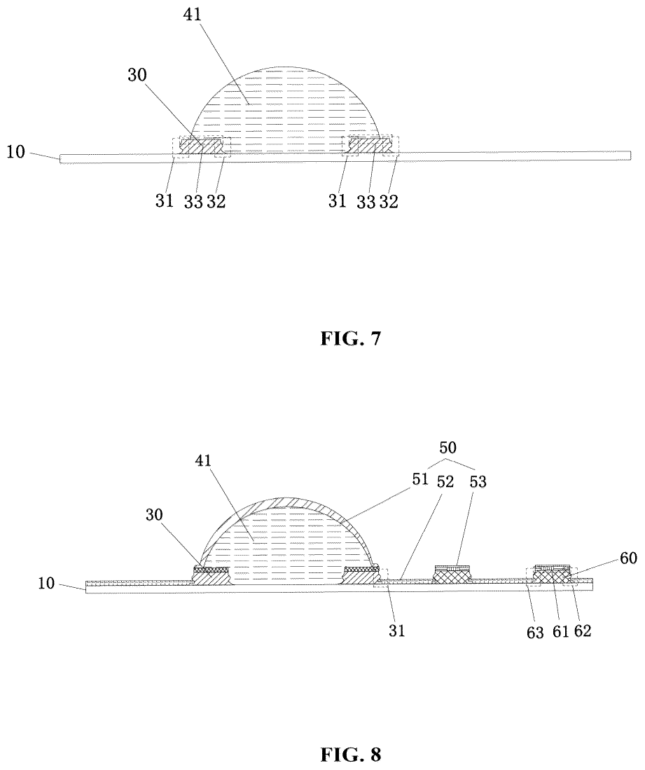

In some optional embodiments, as shown in FIG. 7, before forming the barrier element 40, the method may further include: depositing an organic insulating material on the base substrate 10 to form an organic insulating layer 41 covering the second side surface 32 and at least a portion of the first surface 33.

In the above optional embodiments, as shown in FIG. 7, an organic insulating material may be deposited on the base substrate 10 to form the organic insulating layer 41. The organic insulating layer 41 may be used as the barrier element for blocking ink overflow from the ink layer. The organic insulating layer 41 may cover at least 90% of the first surfaces 33, which may reduce the contact area between the subsequently formed light-emitting structure and the first isolation structures 30. Therefore, the risk of the disconnected light-emitting structures being connected through the first isolation structure 30 may be reduced. Other structures in FIG. 7 such as the first side surface 31, are consistent with FIG. 5, and are not repeated here.

In some optional embodiments, as shown in FIG. 6, before forming the barrier element 40, the method may further include: depositing an inorganic insulating material on the base substrate 10 to form an inorganic insulating layer 42 covering at least a portion of the first surface 33, where the inorganic insulating layer 42 may include a third surface 34 on a side away from the barrier element 40; and depositing an organic insulating material on the base substrate 10 to form an organic insulating layer 41 covering at least a portion of the third surface 34 and the second side surfaces 32.

In the above optional embodiment, as shown in FIG. 6, the barrier element 40 may include the organic insulating layer 41 and the inorganic insulating layer 42. An inorganic insulating material may be first deposited on the first surface 33 to form the inorganic insulating layer 42, and the inorganic insulating layer 42 may completely cover the first surface 33. Then, an organic insulating material may be deposited on the base substrate 10 to form the organic insulating layer 42, forming the completed barrier element 40. The barrier element 40 including the inorganic insulating layer 42 may have a more excellent insulating effect. Since the inorganic insulating layer 42 may completely cover the first surface, the light-emitting structure formed subsequently and the first isolation structures 30 may be insulated from each other, and thus the connection between the separated light-emitting structures may be completely blocked. The organic insulating layer 41 may be deposited on the inorganic insulating layer 42. The organic insulating layer 41 may be located between the first isolation structures 30, and may cover part of the first surfaces of the first isolation structures 30. The structure of the organic insulating layer 41 may be similar to a hemispherical type, which is mainly used to block the overflow of the ink layer. Since the connection between the separated light-emitting structures is blocked, water vapor may be also prevented from entering the display region through the light-emitting structure. Other structures in FIG. 6 such as the first side surface 31, are consistent with FIG. 5, and are not repeated here.

In the above optional embodiments, the process of depositing the above-mentioned organic insulating material may include an inkjet printing process. However, it should noted that the process of forming the above-mentioned organic insulating layer and inorganic insulating layer is not limited to the inkjet printing process, but may also be other deposition processes, such as physical vapor deposition (PVD) process or chemical vapor deposition (CVD), which are not specifically limited in the embodiments of the present disclosure.

After forming the barrier element, as shown in FIG. 8, in S400, the first light-emitting portion 51 may be formed on the barrier element, and the second light-emitting portion 52 may be formed on the base substrate 10. The first light-emitting portion 51 and the second light-emitting portion 52 may be arranged at intervals, and the second light-emitting portion 52 may be in contact with the first side surface 31.

In one embodiment, as shown in FIG. 8, after the barrier element is formed, a light-emitting structure 50 may be deposited on the barrier element, and the light-emitting structure 50 may be isolated by the first isolation structures 30 into the first light-emitting portion 51 and part of the second light-emitting portion 52. Since the thickness of the light-emitting structure 50 is very thin, part of the second light-emitting portion 52 may fall on the first side surface 31 and contact the first side surface 31 at the disconnected places. By making the first light-emitting portion 51 and the second light-emitting portion 52 separated by the first side surface 31 having a groove morphology, the first light-emitting portion 51 and the second light-emitting portion 52 may be made discontinuous, thereby improving the detection stability of the display panel under high temperature and high humidity conditions and also improving the electrostatic discharge capability of the holes set in the display panel. It should noted that the barrier element in FIG. 8 only includes the organic insulating layer 41, which is used as an example only to illustrate the present disclosure. The barrier element may also have other film layers, which are not all shown in the figure.

In some optional embodiments, as shown in FIG. 8, before forming the light-emitting structure 50 on the side of the barrier element away from the base substrate 10, the method may further include: forming at least one second isolation structure 60 on the base substrate 10, where the at least one second isolation structure 60 may include a second surface 61 on the side away from the base substrate 10; forming the third light-emitting portion 53 of the light-emitting structure 50 on the second surface 61; and forming at least one groove on the third side surface 62 and/or the fourth side surface 63 of the at least one second isolation structure 60.

In the above optional embodiments, as shown in FIG. 8, before forming the light-emitting structure 50, the at least one second isolation structure 60 may be first formed on the base substrate 10. When the light-emitting structure 50 is deposited, the at least one second isolation structure 60 may also separate part of the light-emitting structure 50 to form the third light-emitting portion 53 and another part of the second light-emitting portion 52. The second light-emitting portion 52 may fall on two side surfaces of the second isolation structure 60 after separation. The morphology of at least one side surface of the third side surface and the fourth side surface of the second isolation structure 60 may be etched into the morphology of at least one groove. Preferably, the third side surface and the fourth side surface may be both etched with at least one groove, which may more securely block water vapor and prevent water vapor from entering the display region.

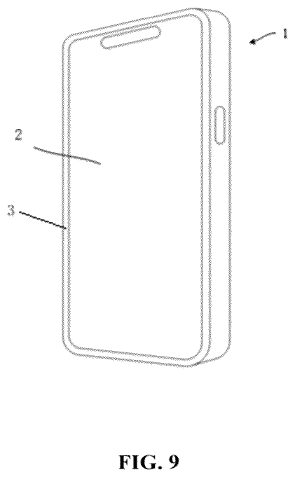

The present disclosure also provides a display device. As shown in FIG. 9 which is a display device provided by the present disclosure, the display device 1 may include a display panel provided by various embodiments of the present disclosure. The display device may include a display region 2 and a non-display region 3.

In the present disclosure, relational terms such as “first” and “second” are only used to distinguish one entity or operation from another entity or operation, and do not necessarily require or imply that there is a relationship between these entities or operations. There is no such actual relationship or sequence. Furthermore, the terms “comprises”, “include”, or any other variations thereof are intended to cover a non-exclusive inclusion such that a process, method, article, or apparatus that includes a list of elements includes not only those elements, but also those not expressly listed, or elements inherent to the process, method, article or equipment. Without further limitation, an element defined by the statement “comprises a . . . ” does not exclude the presence of additional identical elements in a process, method, article, or apparatus that includes the stated element.

Various embodiments have been described to illustrate the operation principles and exemplary implementations. It should be understood by those skilled in the art that the present disclosure is not limited to the specific embodiments described herein and that various other obvious changes, rearrangements, and substitutions will occur to those skilled in the art without departing from the scope of the disclosure. Thus, while the present disclosure has been described in detail with reference to the above described embodiments, the present disclosure is not limited to the above described embodiments, but may be embodied in other equivalent forms without departing from the scope of the present disclosure, which is determined by the appended claims.

What is claimed is:

1. A display panel, comprising a display region and a non-display region, wherein:
the non-display region includes:
a base substrate including an opening area;
first isolation structures on the base substrate and surrounding a periphery of the opening area, wherein one first isolation structure includes a first surface on a side away from the base substrate, and a first side surface and a second side surface opposite to each other in a direction parallel to the base substrate;
a barrier element on the substrate and surrounding the periphery of the opening area, wherein the barrier element covers the second side surface and at least a portion of the first surface, and the second side surface is located on a side close to a center point of a vertical projection of the barrier element on the base substrate; and
a light-emitting structure including a first light-emitting portion and a second light-emitting portion, wherein: the first light-emitting portion is located on a side of the barrier element away from the base substrate, the second light-emitting portion is located on the base substrate and in contact with the first side surface, and the first light-emitting portion and the second light-emitting portion are spaced apart.

2. The display panel according to claim 1, wherein:
the first side surface is an uneven surface; and
the first side surface includes at least one groove, and a part of the second light-emitting portion is in contact with the first side surface.

3. The display panel according to claim 1, wherein:
the barrier element includes an organic insulating layer, and the organic insulating layer covers the second side surface and at least a portion of the first surface.

4. The display panel according to claim 3, wherein:
the barrier element further includes an inorganic insulating layer, wherein the inorganic insulating layer covers at least a portion of the first surface and the organic insulating layer covers at least a portion of the inorganic insulating layer.

5. The display panel according to claim 1, wherein:
an area of the portion of the first surface covered by the barrier element is larger than 90% of a total area of the first surface.

6. The display panel according to claim 1, wherein:
a number of the first isolation structures is two;
in a direction from the barrier element to the opening area, the barrier element includes a first end and a second end opposite to each other; and
the first end and the second end are respectively in contact with the first surfaces of different first isolation structures.

7. The display panel according to claim 1, wherein:
the non-display region further includes at least one second isolation structure located on the base substrate, and the at least one second isolation structure is distributed at intervals along a direction from the barrier element to the opening area.

8. The display panel according to claim 7, wherein:
the at least one second isolation structure includes a second surface on a side away from the base substrate, and the light-emitting structure further includes a third light-emitting portion located on the second surface, wherein the third light-emitting portion is in contact with the second surface and the third light-emitting portion is not in contact with the second light-emitting portion.

9. The display panel according to claim 4, wherein:
each of the first light-emitting portion and the second light-emitting portion includes a light-emitting layer, an electrode layer and an insulating layer, wherein the electrode layer is located on two sides of the light-emitting layer perpendicular to the base substrate, wherein:
a portion of the insulating layer in the first light-emitting portion is in contact with the first surface, and another portion of the insulating layer in the first light-emitting portion is in contact with a surface of the inorganic insulating layer away from the base substrate; and/or the insulating layer in the second light-emitting portion is located between the electrode layer and the first side surface.

10. The display panel according to claim 7, wherein:
a portion of the second light-emitting portion is in contact with the at least one second isolation structure at a side of the at least one second isolation structure close to the opening area, and another portion of the second light-emitting portion is in contact with the at least one second isolation structure at another side of the at least one second isolation structure away from the opening area.

11. The display panel according to claim 7, wherein:
in the direction from the barrier element to the opening area, the at least one second isolation structure includes a third side surface and a fourth side surface opposite to each other, and the third side surface and/or the fourth side surface are uneven surfaces.

12. The display panel according to claim 11, wherein:
the uneven surfaces of the third side surface and/or the fourth side surface include at least one groove, and a portion of the second light-emitting portion is in contact with the uneven surfaces.

13. The display panel according to claim 1, wherein:
the first side surface includes a first portion not covered by the light-emitting structure, and the non-display region further includes a first encapsulation layer, wherein the first encapsulation layer covers a side of the light-emitting structure away from the base substrate and the first portion.

14. The display panel according to claim 13, wherein:
the non-display region further includes a second encapsulation layer, wherein the second encapsulation layer is located on a side of the first encapsulation layer away from the base substrate.

15. A fabrication method of a display panel, comprising forming a display region and a non-display region, wherein:
forming the non-display region includes:
providing a base substrate including an opening area;
forming first isolation structures on the base substrate and surrounding a periphery of the opening area, wherein one first isolation structure includes a first surface on a side away from the base substrate, and a first side surface and a second side surface opposite to each other in a direction parallel to the base substrate;
forming a barrier element on the substrate and surrounding the periphery of the opening area, wherein the barrier element covers the second side surface and at least a portion of the first surface, and the second side surface is located on a side close to a center point of a vertical projection of the barrier element on the base substrate; and
forming a light-emitting structure including a first light-emitting portion on the barrier element and a second light-emitting portion on the base substrate, wherein the first light-emitting portion and the second light-emitting portion are spaced apart and the second light-emitting portion is in contact with the first side surface.

16. The method according to claim 15, wherein forming the first isolation structures on the base substrate includes:
depositing the first isolation structures on the base substrate; and
etching one first side surface of one first isolation structure to form at least one groove.

17. The method according to claim 15, before forming the barrier element, further including:
depositing an organic insulating material on the substrate to form an organic insulating layer covering the second side surface and at least a portion of the first surface.

18. The method according to claim 15, before forming the barrier element, further including:
depositing an inorganic insulating material on the base substrate to form an inorganic insulating layer covering at least a portion of the first surface, wherein the inorganic insulating layer has a third surface on a side away from the barrier element; and
depositing an organic insulating material on the base substrate to form an organic insulating layer covering at least a portion of the third surface and the second side surface.

19. The method according to claim 15, before forming the light-emitting structure including the first light-emitting portion and the second light-emitting portion, further including:
forming at least one second isolation structure on the base substrate, wherein the at least one second isolation structure includes a second surface on a side away from the substrate;
forming a third light-emitting portion of the light-emitting structure on the second surface; and
forming at least one groove on a third side surface and/or a fourth side surface of the at least one second isolation structure.

20. A display device comprising a display panel, wherein:
the display panel includes a display region and a non-display region; and
the non-display region includes:
a base substrate including an opening area;
first isolation structures on the base substrate and surrounding a periphery of the opening area, wherein one first isolation structure includes a first surface on a side away from the base substrate, and a first side surface and a second side surface opposite to each other in a direction parallel to the base substrate;
a barrier element on the substrate and surrounding the periphery of the opening area, wherein the barrier element covers the second side surface and at least a portion of the first surface, and the second side surface is located on a side close to a center point of a vertical projection of the barrier element on the base substrate; and
a light-emitting structure including a first light-emitting portion and a second light-emitting portion, wherein: the first light-emitting portion is located on a side of the barrier element away from the base substrate, the second light-emitting portion is located on the base substrate and in contact with the first side surface, and the first light-emitting portion and the second light-emitting portion are spaced apart.
